(19) United States
(12) Patent Application Publication
(10) Pub. No.: US 2005/0014332 A1
(43) Pub. Date: Jan. 20, 2005

(54) Method to improve bitline contact formation using a line mask

(75) Inventors: Michael Maldei, Durham, NC (US); Johnathan E. Faltermeier, LaGrangeville, NY (US); David M. Dobuzinsky, New Windsor, NY (US); Prakash C. Dev, Plano, TX (US); Thomas Rupp, Faak am see (AT)

Correspondence Address: LERNER, DAVID, LITTENBERG,;KRUMHOLZ & MENTLIK, 600 SOUTH AVENUE WEST, WESTFIELD, NJ, 07090, US

(73) Assignees: Infineon Technologies North America Corp., San Jose, CA (US); International Business Machines Corporation, Armonk, NY (US)

(21) Appl. No.: 10/619,884

(22) Filed: Jul. 15, 2003

(51) Int. Cl. H01L 21/302; H01L 21/336; H01L 21/8242; H01L 21/461

(52) U.S. Cl. 438/248; 438/262; 438/272; 438/282

(57) ABSTRACT

A semiconductor device is fabricated to have improved bitline contact formation. Polysilicon is deposited between gate contacts that connect to transistors of DRAM memory cells. The polysilicon covers the gate contacts and continues to cover the gate contacts during subsequent processing steps. A bitline of, e.g., tungsten, is deposited so that it contacts at least a portion of the polysilicon, thereby providing electrical contact with the DRAM transistors.

### BACKGROUND OF THE INVENTION

The present invention relates to semiconductor fabrication. More particularly, the present invention relates to enhanced bitline contact formation in semiconductor device fabrication.

Semiconductor devices are employed in various systems in a wide variety of applications. An important type of semiconductor device is known as dynamic random access memory (“DRAM”). DRAM is extensively used for memory in computers and other electronic devices. A basic DRAM memory cell typically includes one capacitor and one transistor, which may be formed in a semiconductor substrate. The capacitor stores a charge that can represent a data value. The transistor allows the data value to be refreshed, read from or written to the capacitor.

FIG. 1 illustrates a schematic diagram of a conventional DRAM memory cell 100 comprising a capacitor 110 and a transistor 120. The capacitor 110 includes a first electrode 112 and a second electrode 114, which are separated by a dielectric material (not shown), as is known in the art. The transistor 120 includes a source (or drain) 122 connected to the second electrode 114. The transistor 120 also includes a drain (or source) 124 connected to a bitline 132, as well as a gate 126 connected to a wordline 130. The data value may be refreshed, read from or written to the capacitor 110 by applying appropriate voltage to the bitline 132 and/or the wordline 130.

DRAM and other semiconductor devices are typically fabricated in a series of processing steps. The steps may include depositing material on a semiconductor wafer, patterning the material, etching selected portions of the material, doping, cleaning and repeating one or more of these steps. As used herein, a “semiconductor wafer” means any substrate, microelectronic device, chip or the like, at any stage of fabrication, which is used to form an integrated circuit or other electronic circuitry. Each semiconductor device or component thereof may be formed in one or more regions on or in the semiconductor wafer.

Once a device is fabricated, it may be connected to another device, component or other portion of the semiconductor wafer using metal lines and/or vias in one or more layers of the semiconductor wafer. These interconnections may be formed by, e.g., first etching isolative material and then depositing metal in the etched region. In order to ensure high yield contact of interconnections to such devices, e.g., electrical contact between the interconnections and thousands or millions of devices in the semiconductor wafer, prior solutions have required significant over-etching of the isolative material. Unfortunately, excessive over-etching can damage crucial portions of the semiconductor device, such as the transistor gate contact, as well as other areas of the semiconductor wafer. Therefore, it is desirable to employ a new process that avoids excessive over-etching.

### SUMMARY OF THE INVENTION

In accordance with an embodiment of the present invention, a method of fabricating a semiconductor device is provided. The method includes patterning a mask on a surface of a semiconductor wafer to expose portions of the semiconductor wafer while covering other portions of the semiconductor wafer. Selected portions of the semiconductor wafer are etched to form a plurality of recesses between gate contacts disposed in a first region of the semiconductor wafer. Then, a conductive layer is deposited to fill the recesses and cover the gate contacts. Next, a metal layer is deposited. The metal layer contacts at least a portion of the conductive layer and is an electrical contact with the conductive layer filling the recesses. The method preferably further includes depositing an insulating layer over the conductive layer before depositing the metal layer. In this case, a bitline mask is patterned on the insulating layer and then selected portions of the insulating layer are etched in accordance with the bitline mask to form a trench through the insulating layer to contact the conductive layer. After the selected portions are etched, the metal layer is deposited in the trench. In an alternative, etching the selective portions of the insulating layer is performed using a RIE process. Preferably, the RIE process includes over-etching through the insulating layer to ensure exposure of the conductive layer, while the conductive layer covers the gate contacts after the RIE process. Optionally, the insulating layer is an oxide. Preferably, the oxide is formed using a tetraethyl orthosilicate (TEOS) precursor, as is known in the art. The oxide is preferably at least 1000 Å thick. In a further alternative, the metal layer comprises a refractory metal, which is preferably tungsten. Preferably, the conductive layer comprises silicon. The silicon may be doped. In one alternative, the silicon is polycrystalline silicon (poly-Si). In another alternative, the silicon is amorphous silicon. When using amorphous silicon, the method preferably further includes annealing the amorphous silicon after deposition. Alternatively, the conductive layer comprises tungsten.

In accordance with another embodiment of the present invention, a method of fabricating a semiconductor device is provided. The method includes fabricating a plurality of capacitors and a plurality of transistors in a first region of a semiconductor wafer. The plurality of the transistors each include a source region, a drain region, and a gate region. The plurality of capacitors are in electrical contact with the plurality of transistors to form a plurality of memory cells. Gate contacts are formed in a second region of the semiconductor wafer. Each of the gate contacts is electrically connected to one of the gate regions and has a top surface remote from that gate region. An insulating material is deposited between the gate contacts. Then an oxide is deposited over the insulating material and the gate contacts. The method further includes patterning a mask on a surface of the oxide to expose portions of the semiconductor wafer while covering other portions of the semiconductor wafer. Selected portions of the oxide and the insulating material are etched based upon the mask to form a plurality of recesses between the gate contacts and to expose the top surfaces of the gate contacts. A conducting layer is then deposited to fill the recesses and to cover the top surfaces of the gate contacts. Next, an insulating layer is deposited over the conducting layer. A bitline mask is patterned on the insulating layer and then selected portions of the insulating layer are etched in accordance with the bitline mask to form a trench through the insulating layer to contact the conducting layer. A metal layer is then deposited in the trench, wherein the metal layer contacts at least a portion of the conducting layer so that the metal layer is in electrical contact with the source regions of the plurality of transistors. The method preferably further comprises performing chemical mechanical polishing (CMP) on the conducting layer to produce a substantially planar surface. After CMP the conducting layer still covers the top surfaces of the gate contacts. In an alternative, the metal layer comprises a refractory metal, preferably tungsten. In another alternative, etching the selected portions of the insulated layer is performed using a RIE process. Preferably, the RIE process includes over-etching through the insulating layer to ensure exposure of the conducting layer, while the conducting layer covers the top surfaces of the gate contacts after RIE. In one example, the conducting layer comprises silicon. The silicon layer may be doped. In an alternative, the silicon layer is poly-Si. In another alternative, the silicon layer is amorphous silicon. In another example, the conducting layer comprises tungsten. In a further example, the insulating layer includes an oxide.

In accordance with another embodiment of the present invention, a semiconductor device is provided. The semiconductor device comprises a plurality of capacitors, a plurality of transistors, a plurality of gate contacts, a conductive layer and a bitline contact. The capacitors are formed in a semiconductor substrate. The transistors are formed in the semiconductor substrate and each transistor includes a source region, a drain region and a gate region. Each of the transistors is in electrical contact with a corresponding capacitor. Each of the gate contacts is connected to a corresponding one of the gate regions. The gate contacts each include a top surface remote from the gate region. The conductive layer is adjacent to the source regions and covers the top surfaces of the gate contacts. The bitline contact connects to the conductive layer such that the conductive layer provides electrical contact between the bitline contact and the source regions of the transistors. Preferably, the conductive layer comprises silicon. More preferably, the silicon is either poly-Si or amorphous silicon. The silicon may be doped. optionally, the conductive layer comprises tungsten. In an alternative, the bitline contact comprises a refractory metal. Preferably, the refractory metal is tungsten. In a preferred example, each of the plurality of capacitors includes an outer electrode adjacent to the semiconductor substrate, an inner electrode partially surrounded by the outer electrode and a dielectric material that is disposed between the inner electrode and the outer electrode. More preferably, the drain regions of the transistors are buried straps that are in electrical contact with corresponding inner electrodes of the capacitors.

### BRIEF DESCRIPTION OF THE DRAWINGS

FIG. 1 depicts a schematic of a conventional DRAM memory cell.

FIG. 2 is a schematic cross-sectional view illustrating a step in a process of fabricating a semiconductor device in accordance with an embodiment of the present invention.

FIG. 3 is a schematic cross-sectional view illustrating the result of another step in the process of fabricating a semiconductor device of the present invention.

FIG. 4 is a schematic cross-sectional view illustrating the result of a subsequent step in the process of fabricating a semiconductor device of the present invention.

FIG. 5 is a schematic cross-sectional view illustrating the result of yet another step in the process of fabricating a semiconductor device of the present invention.

FIG. 6 is a schematic cross-sectional view illustrating the result of a further step in the process of fabricating a semiconductor device of the present invention.

FIG. 7 is a schematic cross-sectional view illustrating the result of another step in the process of fabricating a semiconductor device of the present invention.

FIG. 8 is a schematic cross-sectional view illustrating a semiconductor device in accordance with an embodiment of the present invention.

### DETAILED DESCRIPTION

In accordance with an embodiment of the present invention, an enhanced process for fabricating a bitline contact is provided. The materials and processes described below can be employed with various kinds of substrates, including, but not limited to silicon (Si), gallium arsenide (GaAs), indium phosphide (InP), and silicon carbide (SiC). It is to be appreciated that certain steps may be performed in different order, and that the numbers used, e.g., thickness, are approximations and may be varied.

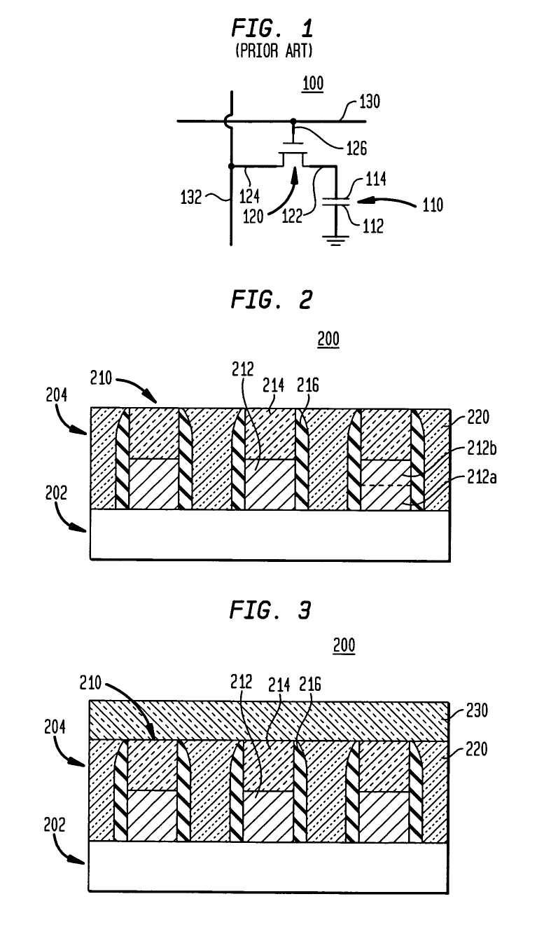

FIG. 2 is a schematic cross-sectional illustration of a semiconductor wafer 200 at a step of a process of fabricating a semiconductor device. It should be appreciated that some of the features in the figures have been exaggerated for illustrative purposes while others have not been shown. It should also be appreciated that the figures are not drawn to scale. The semiconductor wafer 200 may contain numerous semiconductor components and devices in which hundreds, thousands or millions of circuits are manufactured at one time. As shown in FIG. 2, gate contacts 210 may be formed in an upper region 204 over a lower region 202 of the semiconductor wafer 200. By way of example only, the lower region 202 may include transistors and capacitors coupled together to form DRAM memory cells.

The gate contacts 210, also known as gate stacks, preferably comprise a contact portion 212, an insulating cap 214, and spacers 216 on either side of the contact portion 212 and the insulating cap 214. The contact portion 212 is part of a wordline, which has a depth component that extends into the page. The contact portion 212 preferably comprises poly-Si. Alternatively, the contact portion 212 preferably comprises a poly-Si lower layer 212a and an upper layer 212b. The upper layer 212b may be a metal silicide such as tungsten silicide (WSix) or a metal nitride such as tungsten nitride (WN). The insulating cap 214 and the spacers 216 are preferably silicon nitride (SiN). At this stage in the process, a passivation layer 220 may be deposited between the gate contacts 210. The passivation layer 220 is preferably a doped deposited glass material such as boro-phospho-silicate glass (BPSG), phospho-silicate glass (PSG) or boro-silicate glass (BSG). The passivation layer 220 may be deposited by a chemical vapor deposition (CVD) process such as plasma-enhanced CVD (PECVD), as is known in the art. As shown in FIG. 2, the passivation layer 220 has been etched back or recessed to the top surface of the gate contacts 210. This may be performed using CMP.

Next, as shown in FIG. 3, a layer of oxide 230 or other material having similar insulating properties is deposited over the passivation layer 220 and the gate contacts 210. The oxide layer 230 may be deposited using a CVD process such as PECVD or low pressure CVD (LPCVD). In this case, a TEOS precursor may be used. Preferably, the oxide layer 230 is on the order of 750 Å thick, although the thickness may vary depending on various factors, including the feature size of the semiconductor devices being fabricated.

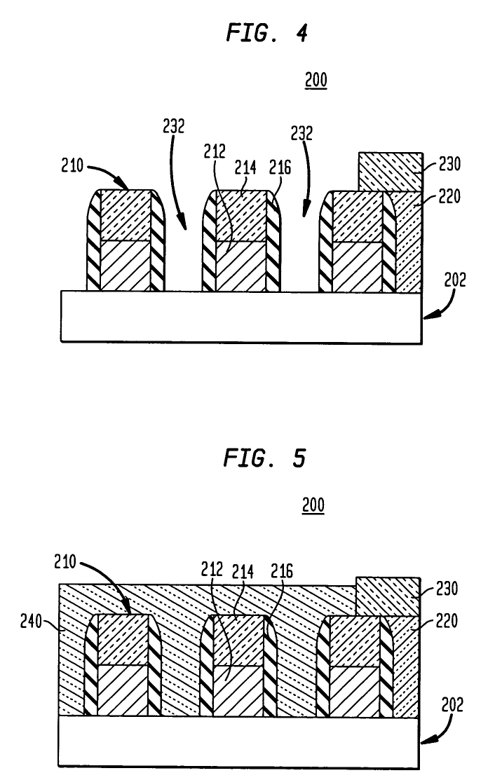

FIG. 4 illustrates a subsequent step after a mask, e.g., a line mask, has been used to pattern the oxide layer 230. As seen in the figure, selected portions of the oxide layer 230 and the passivation layer 220 have been removed based on the mask pattern. Reactive ion etching (RIE) is preferably used to remove the selected portions and define trenches or recesses 232. By way of example only, the selected portions of the passivation layer 220 and the oxide layer 230 may be removed by successive RIE etchings. In this case, an RIE process using C₄F₈ chemistry employing, e.g., C₄F₈, CO, Ar and O₂ gasses may remove the selected portions of the oxide layer 230, as is known in the art. An RIE process using CH₂F₂ chemistry employing, e.g., CH₂F₂, C₄F₈, and Ar gasses may remove the selected portions of the passivation layer 220, as is known in the art.

Then, as shown in FIG. 5, a silicon layer 240 is deposited or otherwise formed to fill the trenches 232 and cover the gate contacts 210. The silicon layer 240 preferably comprises amorphous silicon or poly-Si. If amorphous silicon is employed, it may be annealed in an optional step to at least partially crystallize the material. More preferably, the silicon layer 240 includes a dopant. For example, the silicon may be doped with an N-type material such as phosphorous. The dopant concentration is preferably between 1×10²⁰ and 1×10²¹ atoms per cubic centimeter. The silicon layer 240 may be deposited using a CVD process such as LPCVD, as is known in the art. In another alternative, a conductive material other than silicon can be used instead of the silicon layer 240. The choice of conductive material may be based on properties of the material, such as outdiffusion and electromigration. By way of example only, tungsten (W) may be used. W may be deposited to a desired thickness by a CVD process using WF₆ chemistry employing, e.g., WF₆, SiH₄ H₂ and Ar gasses, as is known in the art.

The silicon layer 240 may be polished or otherwise cleaned by, for example, CMP. However, in order to ensure electrical contact with selected device components, e.g., transistor source or drain regions in the lower region 202 or elsewhere, the silicon layer 240 is not recessed below the tops of the gate contacts 210. Instead, the silicon layer 240 maintains a continuous layer over the gate contacts 210.

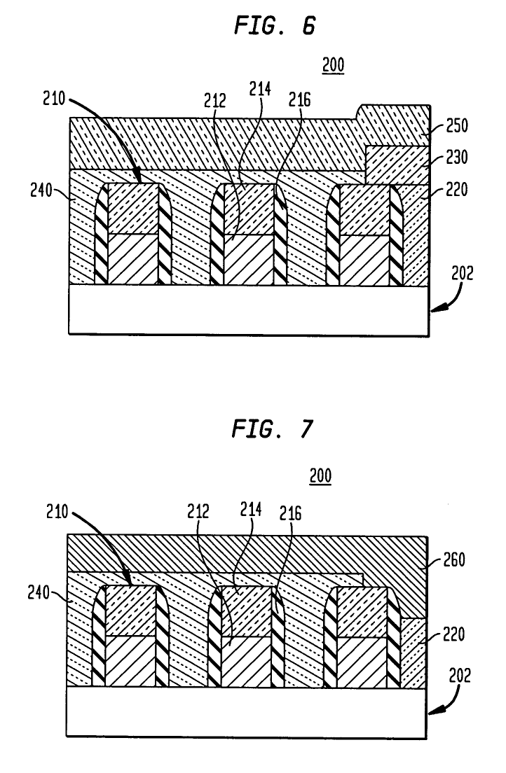

Subsequently, as shown in FIG. 6, an insulating layer 250 may be deposited over the silicon layer 240. The insulating layer is preferably a layer of oxide on the order of 1250 Å thick, although the thickness may vary depending on various factors, including the feature size of the semiconductor devices being fabricated. A TEOS precursor may be used in forming the oxide. Preferably, the oxide thickness is at least 1000 Å.

FIG. 7 illustrates a subsequent step after a bitline mask is used to pattern the insulating layer 250 using, e.g., a line mask. Selected portions of the insulating layer 250 are removed based on the bitline mask pattern. Preferably, the bitline mask pattern is a trench pattern for exposing the silicon layer 240. RIE is preferably used to remove the selected portions. By way of example only, the RIE chemistries discussed above may be used to etch the selected portions of the insulating layer 250. More preferably, the etching process includes over-etching through the insulating layer 250 in order to ensure sufficient exposure of the silicon layer 240. However, excessive overetching, wherein the silicon layer 240 is recessed below the tops of the gate contacts 210, is avoided. Determining the extent of the overetch may be conducted by evaluating the planarity of the deposited layers, or by processing a “split lot” of wafers, as is known in the art. In evaluating the planarity of the deposited layers, an overetch on the order of 300 Å to 500 Å may be employed by way of example only, depending on the degree of planarity. In the split lot case, some of the wafers will be fabricated under a first set of etch conditions and another group of the wafers will be fabricated under a second set of etch conditions. Then, as shown in FIG. 7, a metal layer 260 is formed over the silicon layer 240. The metal layer 260 may be a refractory metal, preferably W, although other metals or metal hybrids may be employed. By way of example only, titanium (Ti), tantalum (Ta) and/or molybdenum (Mo) may also be used. The metal layer 260 is preferably formed by deposition using LPCVD, as is known in the art. For example, when depositing W, the LPCVD deposition chemistry described above may be used. In a further processing step, the metal layer 260 may be polished and/or planarized by CMP. Additional processing, such as adding additional metal and/or device layers, may also be performed.

The process of the present invention is advantageous for multiple reasons. For example, by ensuring that the silicon layer 240 covers the gate contacts 210, the process protects the gate contacts 210 and other components and regions of the semiconductor wafer from erosion during bitline etching. In addition, the continuous covering provides electrical contact to every trench filled by the silicon layer 240, even if the metal layer 260 only contacts the silicon layer 240 at a fraction of the area designated by the bitline mask pattern. This is more robust than past solutions, which required direct contact between the bitline contact and the material in each bitline hole or via.

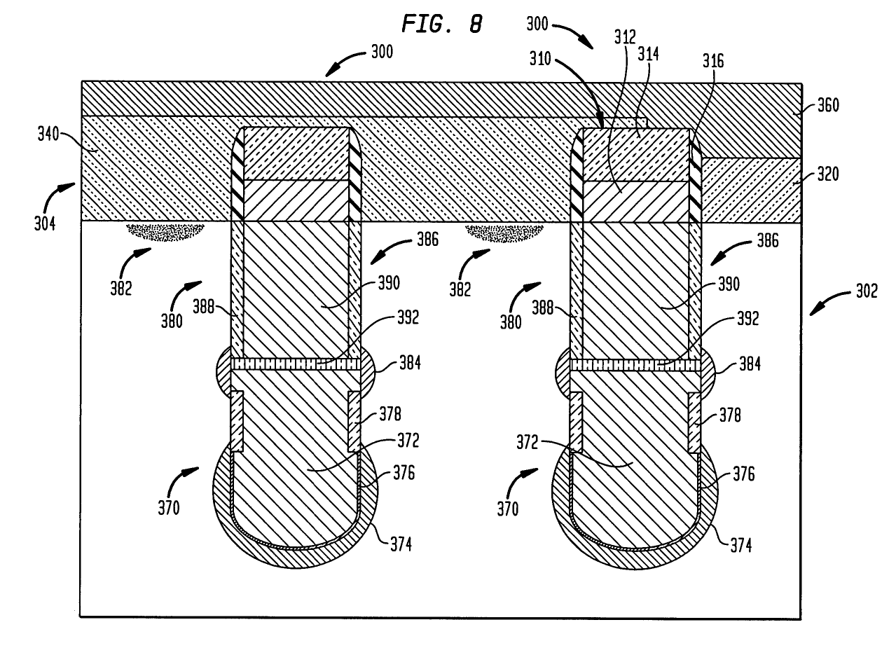

FIG. 8 illustrates a pair of memory cells 300 fabricated in accordance with aspects of the present invention. The memory cells 300 each include a lower region 302 and an upper region 304. A capacitor 370 is electrically connected to a transistor 380 in the lower region 302. The upper region 304 includes bitline and wordline contacts, as will be described below.

The capacitor 370 is shown as a trench capacitor, although other capacitor structures may be used. The capacitor includes an inner electrode 372 and an outer electrode 374 with a dielectric liner 376 (node dielectric) therebetween. The inner electrode 372 is partly surrounded by a collar 378. The collar 378, preferably an oxide, is used to isolate the inner electrode 372 from the substrate in the lower region 302.

The transistor 380 includes a source region 382, a drain region 384 and a gate region 386. The gate region 386 includes a gate material 390 and a gate oxide 388. The drain region 384, also known as a buried strap, provides electrical connectivity between the capacitor 370 and the transistor 380. A trench top oxide (TTO) 392 or equivalent material separates the inner electrode 372 from the gate region 386.

The gate material 390 connects to a contact portion 312 of a gate contact 310. The contact portion 312 is part of a wordline. The gate contact also includes an insulating cap 314 and spacers 316 on either side of the contact portion 312 and the insulating cap 314. A passivation layer 320 may be partly disposed adjacent to the gate contact 310. The source region 382 connects to a metal layer 360, or bitline, through a silicon layer 340. As seen in the figure, the silicon layer 340 fills the space between the gate contacts 310 and overlays the top surfaces of the insulating caps 314 and directly contacts the metal layer 360, providing electrical connectivity to each source region 382. As noted above, a conductive material other than silicon may be used in place of the silicon layer 340.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of fabricating a semiconductor device, comprising:
patterning a mask on a surface of a semiconductor wafer to expose portions of the semiconductor wafer while covering other portions of the semiconductor wafer;
etching selected portions of the semiconductor wafer to form a plurality of recesses between gate contacts disposed in a first region of the semiconductor wafer;
depositing a conductive layer to fill the recesses and to cover the gate contacts; and
depositing a metal layer, wherein the metal layer contacts at least a portion of the conductive layer and is in electrical contact with the conductive layer filling the recesses.

2. The method of claim 1, further comprising:
depositing an insulating layer over the conductive layer prior to depositing the metal layer;
patterning a bitline mask on the insulating layer; and
etching selected portions of the insulating layer in accordance with the bitline mask to form a trench through the insulating layer to contact the conductive layer, wherein the metal layer is deposited in the trench.

3. The method of claim 2, wherein etching the selected portions of the insulating layer is performed using a RIE process.

4. The method of claim 3, wherein the RIE process includes over-etching through the insulating layer to ensure exposure of the conductive layer and the conductive layer covers top surfaces of the gate contacts after the RIE process.

5. The method of claim 2, wherein the insulating layer is an oxide.

6. The method of claim 5, wherein the oxide is formed from a TEOS precursor.

7. The method of claim 6, wherein the oxide is at least 1000 Å thick.

8. The method of claim 1, wherein the metal layer comprises a refractory metal.

9. The method of claim 8, wherein the refractory metal is tungsten.

10. The method of claim 1, wherein the conductive layer comprises silicon.

11. The method of claim 10, wherein the silicon is poly-Si.

12. The method of claim 10, wherein the silicon is amorphous silicon.

13. The method of claim 12, further including annealing the amorphous silicon after deposition.

14. The method of claim 10, wherein the silicon is doped.

15. The method of claim 1, wherein the conductive layer comprises tungsten.

16. A method of fabricating a semiconductor device, comprising:
fabricating a plurality of capacitors and a plurality of transistors in a first region of a semiconductor wafer, the plurality of transistors each including a source region, a drain region and a gate region and the plurality of capacitors being in electrical contact with the plurality of transistors to form a plurality of memory cells;
forming gate contacts in a second region of the semiconductor wafer, each of the gate contacts being electrically connected to one of the gate regions and having a top surface remote from the gate region;
depositing an insulating material between the gate contacts;
depositing an oxide over the insulating material and the gate contacts;
patterning a mask on a surface of the oxide to expose portions of the semiconductor wafer while covering other portions of semiconductor wafer;
etching selected portions of the oxide and the insulating material based on the mask to form a plurality of recesses between the gate contacts and to expose the top surfaces of the gate contacts;
depositing a conducting layer to fill the recesses and to cover the top surfaces of the gate contacts;
depositing an insulating layer over the conducting layer;
patterning a bitline mask on the insulating layer;
etching selected portions of the insulating layer in accordance with the bitline mask to form a trench through the insulating layer to contact the conducting layer; and
depositing a metal layer in the trench, wherein the metal layer contacts at least a portion of the conducting layer so that the metal layer is in electrical contact with the source regions of the plurality of transistors.

17. The method of claim 16, further comprising performing CMP on the conducting layer to produce a substantially planar surface, wherein the conducting layer covers the top surfaces of the gate contacts after CMP.

18. The method of claim 16, wherein the metal layer comprises a refractory metal.

19. The method of claim 18, wherein the refractory metal is tungsten.

20. The method of claim 16, wherein etching the selected portions of the insulating layer is performed using a RIE process.

21. The method of claim 20, wherein the RIE process includes over-etching through the insulating layer to ensure exposure of the conducting layer and the conducting layer covers the top surfaces of the gate contacts after the RIE process.

22. The method of claim 16, wherein the conducting layer comprises silicon.

23. The method of claim 22, wherein the silicon layer is poly-Si.

24. The method of claim 22, wherein the silicon layer is amorphous silicon.

25. The method of claim 22, wherein the silicon is doped.

26. The method of claim 16, wherein the conducting layer comprises tungsten.

27. The method of claim 16, wherein the insulating layer includes an oxide.

28. A semiconductor device comprising:
a plurality of capacitors formed in a semiconductor substrate;
a plurality of transistors formed in the semiconductor substrate, each transistor including a source region, a drain region and a gate region, and each of the plurality of transistors being in electrical contact with a corresponding one of the plurality of capacitors;
a plurality of gate contacts each electrically connected to a corresponding one of the gate regions of the plurality of transistors, the plurality of gate contacts each including a top surface remote from the gate regions;
a conductive layer adjacent to the source regions and covering the top surfaces of the plurality of gate contacts; and
a bitline contact connected to the conductive layer, wherein the conductive layer provides electrical contact between the bitline contact and the source regions of the plurality of transistors.

29. The semiconductor device of claim 28, wherein the conductive layer comprises silicon.

30. The semiconductor device of claim 29, wherein the silicon is poly-Si.

31. The semiconductor device of claim 29, wherein the silicon is amorphous silicon.

32. The semiconductor device of claim 29, wherein the silicon is doped.

33. The semiconductor device of claim 28, wherein the conductive layer comprises tungsten.

34. The semiconductor device of claim 28, wherein the bitline contact comprises a refractory metal.

35. The semiconductor device of claim 32, wherein the refractory metal is tungsten.

36. The semiconductor device of claim 28, wherein each of the plurality of capacitors includes an outer electrode adjacent to the semiconductor substrate, an inner electrode partly surrounded by the outer electrode and a dielectric material disposed between the inner electrode and the outer electrode.

37. The semiconductor device of claim 34, wherein the drain regions of the plurality of transistors are buried straps in electrical contact with corresponding ones of the inner electrodes of the plurality of capacitors.
